(19) United States
(12) Patent Application Publication
(10) Pub. No.: US 2026/0324451 A1
(43) Pub. Date: Oct. 15, 2026

(54) SEMICONDUCTOR DEVICE, METHOD OF MANUFACTURING SEMICONDUCTOR DEVICE, AND POWER CONVERSION APPARATUS

(71) Applicant: Mitsubishi Electric Corporation, Tokyo (JP)

(72) Inventor: Yasunari HINO, Tokyo (JP)

(73) Assignee: Mitsubishi Electric Corporation, Tokyo (JP)

(21) Appl. No.: 19/549,872

(22) Filed: Feb. 25, 2026

(30) Foreign Application Priority Data
Apr. 14, 2025 (JP) 2025-066207

(51) Int. Cl. H10W 70/00; H10W 40/20; H10W 70/05; H10W 70/60; H10W 70/65; H10W 72/00; H10W 72/30; H10W 90/00; H10W 90/10

(52) U.S. Cl. CPC H10W 70/099; H10W 40/235; H10W 70/614; H10W 70/65; H10W 72/347; H10W 72/884; H10W 90/10; H10W 90/734; H10W 90/736; H10W 90/753

(57) ABSTRACT

A semiconductor device includes a circuit pattern and a terminal. The circuit pattern is provided on an upper surface of an insulating layer and is electrically connected to a semiconductor element. The terminal includes a bonding portion bonded to the circuit pattern, and is connectable to an external circuit. The bonding portion includes a region solid-phase bonded to the circuit pattern and a region laser-bonded thereto.

### BACKGROUND

### Technical Field

The present disclosure relates to a semiconductor device, a method of manufacturing a semiconductor device, and a power conversion apparatus.

### Description of the Background Art

The semiconductor device described in Japanese Patent Application Laid-Open No. 2023-040253 has a configuration in which terminals are bonded to an electrode pattern on a substrate by laser welding.

The terminal of the semiconductor device described in Japanese Patent Application Laid-Open No. 2023-040253 has a complicated shape having a bent portion. It is difficult to arrange the laser welding portion of the terminal and the substrate so as to be in contact with each other in a parallel state. When the positional relationship between the terminal and the substrate is not parallel, bonding failure or damage to the substrate may be caused.

### SUMMARY

In order to solve the above problems, an object of the present disclosure is to provide a semiconductor device that realizes stable laser-bonding and has high reliability.

A semiconductor device according to the present disclosure includes a circuit pattern and a terminal. The circuit pattern is provided on the upper surface of the insulating layer and is electrically connected to the semiconductor element. The terminal includes a bonding portion bonded to the circuit pattern, and is connectable to an external circuit. The bonding portion includes a region solid-phase bonded to the circuit pattern and a region laser-bonded thereto.

According to the present disclosure, a semiconductor device that realizes stable laser-bonding and has high reliability is provided.

Objects, features, aspects, and advantages of the present disclosure will become more apparent from the following detailed description and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating a configuration of a semiconductor device according to a first preferred embodiment;

FIG. 2 is a top view illustrating a configuration of a bonding portion of a terminal and a circuit pattern of an insulating substrate;

FIG. 3 is a cross-sectional view illustrating a configuration of a bonding portion of a terminal and a circuit pattern of an insulating substrate;

FIG. 4 is a flowchart illustrating a method of manufacturing the semiconductor device according to the first preferred embodiment;

FIG. 5 is a view illustrating a state in which a bonding portion of a terminal is disposed on a circuit pattern;

FIG. 6 is a view illustrating a state in which a bonding portion of a terminal is disposed on a circuit pattern;

FIG. 7 is a cross-sectional view illustrating a configuration of a bonding portion of a terminal and an insulating substrate in a tacking process;

FIG. 8 is a top view illustrating a configuration of a bonding portion of a terminal and an insulating substrate after a tacking process;

FIG. 9 is a cross-sectional view illustrating a configuration of a bonding portion of a terminal and an insulating substrate in a laser welding process;

FIG. 10 is a top view illustrating a configuration of a bonding portion of a terminal and an insulating substrate in a laser welding process;

FIG. 11 is a cross-sectional view illustrating a bonding failure state between a terminal and an insulating substrate;

FIG. 12 is a cross-sectional view illustrating a bonding failure state between a terminal and an insulating substrate;

FIG. 13 is a top view illustrating another configuration of a bonding portion of a terminal and a circuit pattern of an insulating substrate;

FIG. 14 is a top view illustrating a configuration of a bonding portion of a terminal according to a second preferred embodiment;

FIG. 15 is a top view illustrating the configuration of the bonding portion of the terminal according to the second preferred embodiment;

FIG. 16 is a top view illustrating a configuration of a bonding portion of a terminal according to a third preferred embodiment;

FIG. 17 is a cross-sectional view illustrating another example of the configuration of the bonding portion of the terminal;

FIG. 18 is a cross-sectional view illustrating a configuration of a bonding portion of a terminal according to a fourth preferred embodiment;

FIG. 19 is a cross-sectional view illustrating a configuration of a bonding portion of a terminal according to a fifth preferred embodiment;

FIG. 20 is a cross-sectional view illustrating a configuration of a bonding portion of a terminal according to a sixth preferred embodiment;

FIG. 21 is a flowchart illustrating a method of manufacturing a semiconductor device according to the sixth preferred embodiment;

FIG. 22 is a cross-sectional view illustrating a configuration of a semiconductor device according to a seventh preferred embodiment;

FIG. 23 is a cross-sectional view illustrating a configuration of a semiconductor device according to an eighth preferred embodiment;

FIG. 24 is a flowchart illustrating a method of manufacturing the semiconductor device according to the eighth preferred embodiment;

FIG. 25 is a flowchart illustrating a method of manufacturing in a case where a metal sheet is provided;

FIG. 26 is a cross-sectional view illustrating a configuration of a semiconductor device according to a ninth preferred embodiment;

FIG. 27 is a cross-sectional view illustrating a configuration of a semiconductor device according to a tenth preferred embodiment;

FIG. 28 is a cross-sectional view illustrating a configuration of a semiconductor device according to an eleventh preferred embodiment; and

FIG. 29 is a functional block diagram illustrating a configuration of a power conversion system according to a twelfth preferred embodiment.

### DESCRIPTION OF THE PREFERRED EMBODIMENTS

### First Preferred Embodiment

### (Configuration of Semiconductor Device)

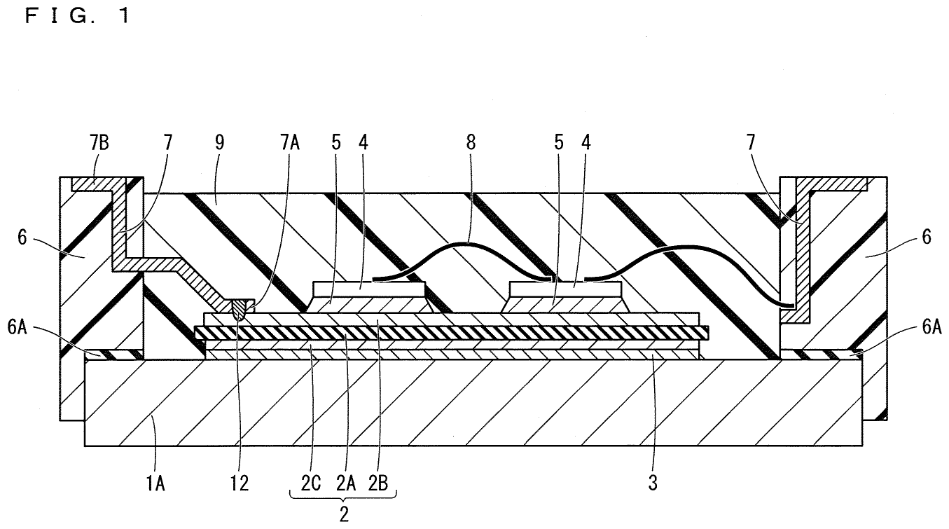

FIG. 1 is a cross-sectional view illustrating a configuration of a semiconductor device according to a first preferred embodiment. The semiconductor device includes a cooler 1A, an insulating substrate 2, a bonding material 3, a semiconductor element 4, a bonding material 5, a case 6, a terminal 7, wiring 8, and a sealing resin 9.

The cooler 1A is a plate made of a material having high thermal conductivity. The cooler 1A is made of, for example, a metal material such as copper (Cu), aluminum (Al), or a copper-molybdenum alloy (CuMo). Alternatively, the cooler 1A may be made of a silicon carbide-aluminum composite (AlSiC), a silicon carbide-magnesium composite (MgSiC), or the like. The cooler 1A according to the first preferred embodiment contains any one of copper and aluminum as a main component. When the cooler 1A is made of copper, the exterior surface is oxidized to deteriorate appearance in appearance, so that exterior plating is performed. In addition, a finned cooler may be further attached to the lower surface of the cooler 1A via heat dissipation grease or a thermal interface material (TIM).

The insulating substrate 2 is provided on the upper surface of the cooler 1A via the bonding material 3. The insulating substrate 2 has a three-layer structure and includes an insulating layer 2A, a circuit pattern 2B, and a heat dissipation layer 2C. The insulating layer 2A is formed of, for example, a ceramic material, and contains, for example, any of aluminum nitride (AlN), silicon nitride (Si₃N₄), and alumina (Al₂O₃). The circuit pattern 2B is provided on the upper surface of the insulating layer 2A. The heat dissipation layer 2C is provided on the lower surface of the insulating layer 2A. The circuit pattern 2B and the heat dissipation layer 2C are formed of metal containing copper. The surfaces of the circuit pattern 2B and the heat dissipation layer 2C may be subjected to exterior treatment by nickel (Ni) plating or the like. The thickness of the circuit pattern 2B is, for example, about 0.2 mm or more and 0.5 mm or less.

The semiconductor element 4 is provided on the circuit pattern 2B of the insulating substrate 2 via the bonding material 5. The bottom electrode of the semiconductor element 4 is electrically connected to the circuit pattern 2B via the bonding material 5. In FIG. 1, two semiconductor elements 4 are mounted. One side of the semiconductor element 4 is about 1.5 mm or more and 15 mm or less. The semiconductor element 4 is formed of, for example, silicon (Si). Alternatively, the semiconductor element 4 may be formed of a wide band gap semiconductor having a band gap larger than that of silicon. The wide band gap semiconductor is, for example, silicon carbide (SiC), gallium nitride (GaN), gallium oxide (Ga₂O₃), diamond (C), or the like. The semiconductor element 4 is a so-called power semiconductor element that controls power. The semiconductor element 4 is, for example, an insulated gate bipolar transistor (IGBT), a metal-oxide-semiconductor field effect transistor (MOSFET), a Schottky barrier diode, or the like. Alternatively, the semiconductor element 4 may be a reverse-conducting IGBT (RC-IGBT) in which an IGBT and a freewheeling diode are integrated on one semiconductor chip.

The bonding material 3 and the bonding material 5 are, for example, solder materials containing tin (Sn) as a main component. In order to improve wettability between the solder material and the surface to be bonded, nickel plating, silver (Ag) plating, or tin plating may be applied to the surface to be bonded. The thickness of the plating is 0.001 mm or more and 0.002 mm or less. When the bonding material 5 is a solder material, plate-like solder, rod-like solder, paste solder, or the like is used in the manufacturing process of the semiconductor device. However, the aspect of the solder material in the manufacturing process is not limited thereto.

The bonding material 3 and the bonding material 5 may be a sintered material containing silver, copper, nickel, or the like. In the manufacturing process of the semiconductor device, the sintered material before sintering contains metal fine particles formed of silver, copper, nickel, or the like. The diameter of the metal fine particles is nano-sized or micron-sized. The metal fine particles may be a mixture of nano-sized and micron-sized particles. In the sintered material before sintering, an organic film is formed around the metal fine particles so that the metal fine particles do not aggregate, and the sintered material is formed into a paste by a solvent. In the manufacturing process of the semiconductor device, the sintered material is heated to about 200° C. or higher and 300° C. or lower while being not pressurized or pressurized at about 1 MPa or higher and 30 MPa or lower. The bonding state in which the pressure treatment is performed is better than the bonding state in which the pressure treatment is not performed. The sintered material containing the metal has a higher thermal conductivity than the solder material, and thus is effective for heat dissipation of the semiconductor element 4.

The case 6 is provided so as to surround the outer peripheries of the insulating substrate 2 and the semiconductor element 4. The case 6 has, for example, a frame shape, and is fixed to the cooler 1A via an adhesive 6A. The case 6 and the upper surface of the cooler 1A form a container shape having the cooler 1A as a bottom surface. The case 6 is formed of a resin having a high thermal softening point. The resin having a high thermal softening point is a material that is not thermally deformed in a use temperature range of the semiconductor device and has insulating properties. The resin having a high thermal softening point is, for example, polyphenylene sulfide (PPS).

The terminal 7 is a conductor configured to be connectable to an external circuit (not illustrated) provided outside the semiconductor device. The terminal 7 is fixed to the case 6 in a state where a part of the terminal 7 is inserted into the case 6. In the manufacturing process of the case 6, the terminal 7 is integrally molded with the case 6. The terminal 7 includes a bonding portion 7A and an exposed portion 7B. The bonding portion 7A is provided at an end portion of the terminal 7, is exposed from the case 6, and is bonded to the circuit pattern 2B of the insulating substrate 2. The bonding portion 7A is disposed in parallel to the circuit pattern 2B. The exposed portion 7B is provided at an end portion of the terminal 7 on a side opposite to the bonding portion 7A. The exposed portion 7B is exposed from the case 6 and has a configuration connectable to an external circuit. For example, the terminal 7 is connected to an external circuit by screw fastening at the exposed portion 7B.

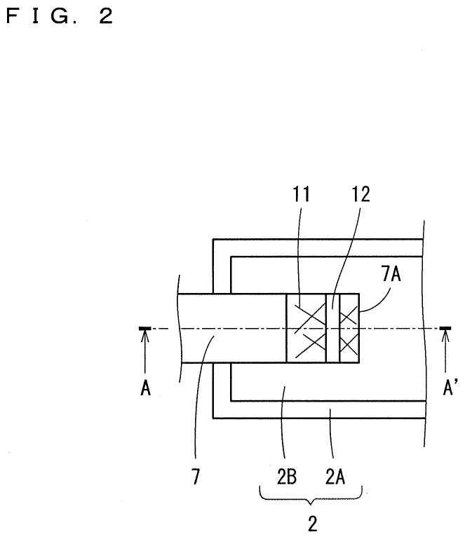

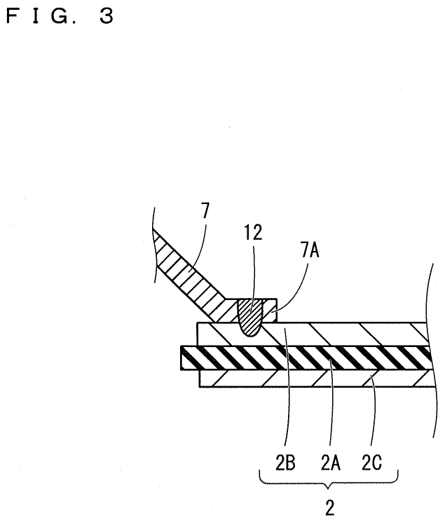

FIG. 2 is a top view illustrating a configuration of the bonding portion 7A of the terminal 7 and the circuit pattern 2B of the insulating substrate 2. FIG. 3 is a cross-sectional view illustrating a configuration of the bonding portion 7A of the terminal 7 and the circuit pattern 2B of the insulating substrate 2. FIG. 3 illustrates a cross section taken along line A-A′ in FIG. 2.

The bonding portion 7A of the terminal 7 includes an indentation 11 and a melting mark 12 on the surface of the bonding portion 7A. The melting mark 12 is formed, for example, in a region where the indentation 11 is formed on the surface of the bonding portion 7A. The indentation 11 is formed around the melting mark 12 and is not formed inside the melting mark 12. The melting mark 12 of the first preferred embodiment is formed in a line shape. The melting mark 12 has, for example, a bead shape (not illustrated) including unevenness in the extending direction of the line.

The back surface of the bonding portion 7A of the terminal 7 is bonded to the circuit pattern 2B. The melting mark 12 is formed from the surface of the bonding portion 7A to the surface layer of the circuit pattern 2B in the thickness direction of the bonding portion 7A. On the back surface of the bonding portion 7A, the bonding portion 7A includes a region solid-phase bonded to the circuit pattern 2B and a region laser-bonded thereto. For example, the solid-phase bonded region is provided around the melting mark 12, that is, around the laser-bonded region.

The terminal 7 is, for example, a member obtained by processing a metal flat plate into a predetermined shape. The terminal 7 of the first preferred embodiment has a bent portion. The bent portion is formed by, for example, a forming process in the manufacturing process of the terminal 7. Although the terminal 7 is made of copper, the material of the terminal 7 is not limited to copper. The material of the terminal 7 may have conductivity and heat dissipation predetermined based on the specifications of the semiconductor device. The material of the terminal 7 may be formed of an alloy containing copper or a composite material having a laminated structure. The thickness of the terminal 7 is selected according to the current capacity of the semiconductor device. The thickness of the terminal 7 is about 0.3 mm or more and 2.0 mm or less, and has a constant thickness. When a rated current exceeds 1000 A as in a semiconductor device for an automobile or an electric railway, the thickness of the terminal 7 exceeds 1.0 mm. Nickel plating, silver plating, or tin plating is applied to the end portion of the terminal 7, particularly the exposed portion 7B. The thickness of the plating is about 0.001 mm or more and 0.002 mm or less.

The wiring 8 electrically connects the semiconductor element 4, the terminal 7, and the circuit pattern 2B. The wiring 8 is formed of, for example, a metal containing any of aluminum, copper, silver, and gold (Au). Alternatively, the wiring 8 may be formed of an alloy containing a plurality of metals among these metals. In the manufacturing process of the semiconductor device, the wiring 8 is bonded to the bonding point of each component by ultrasonic vibration while applying a load. The diameter of the wiring 8 is selected according to the current capacity of the semiconductor device. The diameter of the wiring 8 is 200 μm or more and 500 μm or less. Two bonding points may be connected in parallel by a plurality of wirings 8. Only a minute current of about 1 A flows through the wiring 8 connected to the control electrode of the semiconductor element 4. Therefore, the wiring 8 connected to the control electrode has a diameter less than or equal to the above.

The sealing resin 9 is filled in a container-shaped space inside the case 6. The sealing resin 9 seals components housed inside the case 6, such as the insulating substrate 2, the semiconductor element 4, a part of the terminal 7, and the wiring 8. The sealing resin 9 is, for example, a silicone gel, an epoxy resin, or the like, but is not limited thereto. The sealing resin 9 may be any resin as long as it has an elastic modulus capable of securing adhesion and heat resistance capable of securing reliability. The sealing resin 9 preferably has heat resistance of, for example, 150° C. or higher.

### (Method of Manufacturing Semiconductor Device)

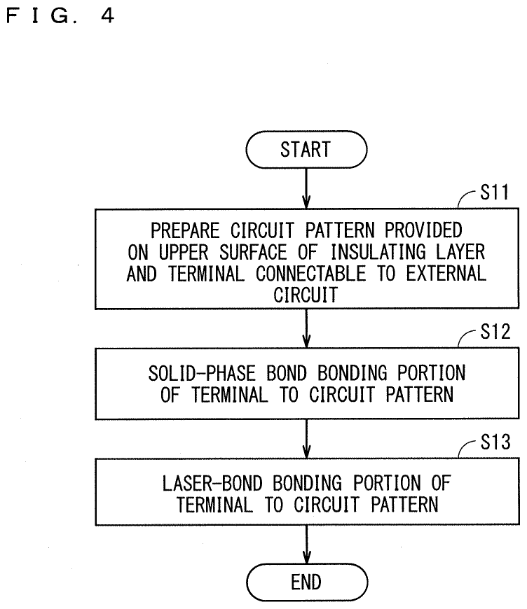

Next, a method of manufacturing a semiconductor device will be described. FIG. 4 is a flowchart illustrating a method of manufacturing the semiconductor device according to the first preferred embodiment.

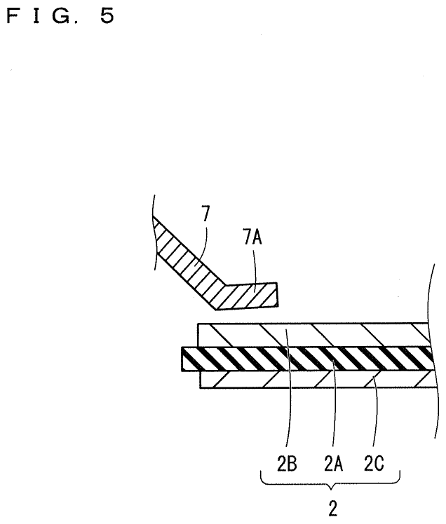

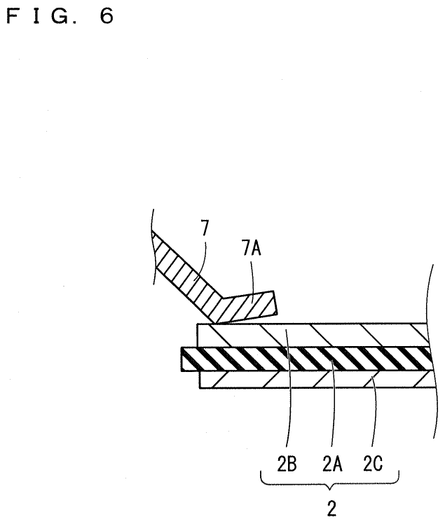

In step S11, the circuit pattern 2B provided on the upper surface of the insulating layer 2A and the terminal 7 connectable to an external circuit are prepared. In the first preferred embodiment, the insulating substrate 2 and the terminal 7 are prepared. When a part of the terminal 7 is inserted into and fixed to the case 6, the terminal 7 integrally molded with the case 6 is prepared. Next, the bonding portion 7A of the terminal 7 is disposed on the circuit pattern 2B. The terminal 7 is fixed by, for example, a semi-finished product (in-process product) of a semiconductor device disposed on a stage in an ultrasonic bonding apparatus (not illustrated). Hereinafter, a semi-finished product of the semiconductor device is referred to as a workpiece. FIGS. 5 and 6 are diagrams illustrating a state in which the bonding portion 7A of the terminal 7 is disposed on the circuit pattern 2B. The terminal 7 has a complicated shape such as a bent portion. In addition, the terminal 7 is fixed to the case 6 in a state where a part of the terminal 7 is inserted into the case 6. Therefore, when the terminal 7 is disposed on the insulating substrate 2, the terminal 7 and the insulating substrate 2 are likely to be displaced in the height direction (vertical direction in FIGS. 5 and 6). For example, the bonding portion 7A illustrated in FIG. 5 is not in contact with the circuit pattern 2B. The bonding portion 7A illustrated in FIG. 6 is not disposed in parallel to the circuit pattern 2B.

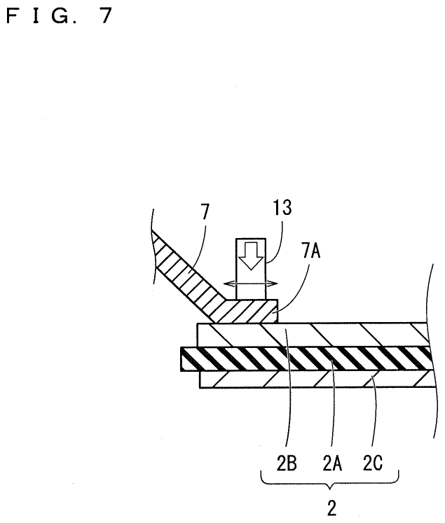

In step S12, the bonding portion 7A of the terminal 7 is solid-phase bonded to the circuit pattern 2B. Here, ultrasonic bonding is used as solid-phase bonding. FIG. 7 is a cross-sectional view illustrating a configuration of the bonding portion 7A of the terminal 7 and the insulating substrate 2 in a tacking process. First, a tool 13 of the ultrasonic bonding apparatus descends and comes into contact with the surface of the bonding portion 7A of the terminal 7, and a load is applied from the tool 13 to the bonding portion 7A. As a result, the bonding portion 7A is corrected to be parallel or nearly parallel to the circuit pattern 2B, and at least a part of the back surface of the bonding portion 7A comes into contact with the circuit pattern 2B. In this state, ultrasonic vibration is applied from the tool 13, and the back surface of the bonding portion 7A is tacked to the circuit pattern 2B. More specifically, the ultrasonic vibration causes friction on the contact surface between the back surface of the bonding portion 7A and the circuit pattern 2B of the insulating substrate 2. The oxide film on each surface is repelled by the friction, and the bonding portion 7A is solid-phase bonded to the circuit pattern 2B by plastic deformation. After the bonding is completed, the tool 13 is raised. The direction of the ultrasonic vibration is basically one direction, but may be two directions. The ultrasonic frequency is, for example, 20 kHz or more and 40 kHz or less. The ultrasonic frequency may be 60 kHz or more and 80 kHz or less, and in this case, gentle ultrasonic bonding to the insulating substrate 2 is realized. The amplitude is about several μm.

Solid-phase bonding in this tacking process is bonding to such an extent that a state in which the bonding portion 7A is parallel to the circuit pattern 2B is maintained. The bonding portion 7A may be tacked to the circuit pattern 2B so that the gap between the back surface of the bonding portion 7A and the circuit pattern 2B is as small as possible. In such a tacking process, since metal burrs and chips are hardly generated, occurrence of a short circuit in the semiconductor device due to the metal burrs and chips is avoided. In addition, an air blowing process after ultrasonic bonding is reduced, and the production process is shortened. A plurality of terminals 7 are provided in the semiconductor device, and a tacking process is performed on the plurality of bonding portions 7A by the movement of the workpiece.

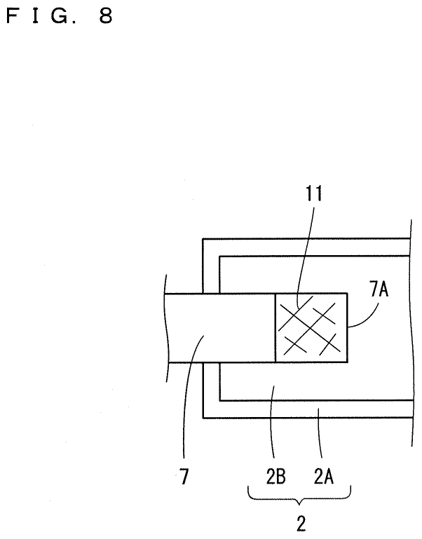

A cross or knurled groove is provided on the lower surface of the tool 13 in contact with the surface of the bonding portion 7A. The terminal 7 is reliably held by the groove, and ultrasonic energy is conducted from the tool 13 to the bonding portion 7A and the circuit pattern 2B. FIG. 8 is a top view illustrating the configuration of the bonding portion 7A of the terminal 7 and the insulating substrate 2 after the tacking process. After the tacking process, the groove pattern on the lower surface of the tool 13 is transferred to the surface of the bonding portion 7A, and the indentation 11 is formed.

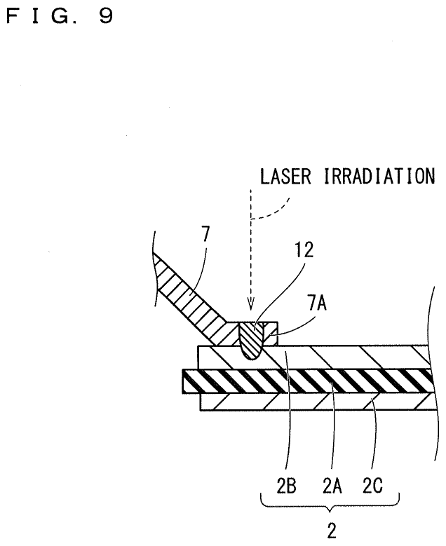

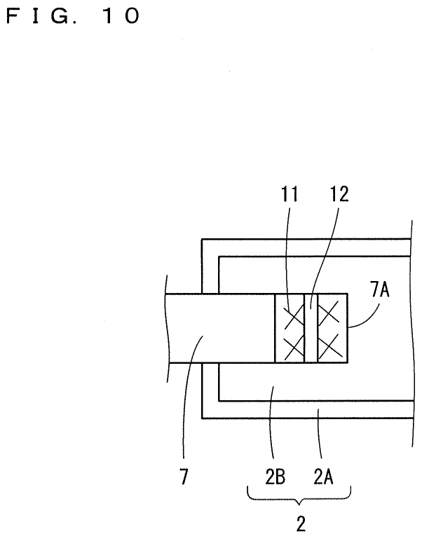

In step S13, the bonding portion 7A of the terminal 7 is laser-bonded to the circuit pattern 2B. First, a workpiece is placed inside a laser apparatus (not illustrated). FIG. 9 is a cross-sectional view illustrating the configuration of the bonding portion 7A of the terminal 7 and the insulating substrate 2 in a laser welding process. In the laser welding process, the surface of the bonding portion 7A opposite to the back surface of the bonding portion 7A tacked to the circuit pattern 2B is irradiated with a laser beam. The laser is applied to the surface of the bonding portion 7A in a dotted manner or in a beam scanned in a linear manner. FIG. 10 is a top view illustrating a configuration of bonding portion 7A of terminal 7 and insulating substrate 2 in the laser welding process. The melting marks 12 are formed in a line shape by linear laser scanning. The laser is scanned by operation of a galvano scanner or a head. The laser may be irradiated linearly while drawing an arc or a spiral. Such scanning secures an area for laser-bonding.

In addition, the laser may be applied to a member around the bonding portion 7A or may be slightly inclined with respect to the scanning direction of the laser.

The spot diameter of the laser irradiation is about 0.05 mm or more and 2.0 mm or less. The laser irradiation time is within 1 s. Such laser irradiation achieves a highly productive laser welding process in a short time. In addition, since the laser-bonding locally heats the bonding point, warpage of the insulating substrate 2 at the time of bonding is reduced, and metal burrs and chips are not generated.

The laser apparatus of the first preferred embodiment includes oscillators that each oscillate blue (wavelength of about 450 nm) and near-infrared (wavelength of about 1070 nm) lasers. Each of the two oscillators can emit a laser of approximately 5 kW or more and 12 kW or less according to the thickness of the bonding portion 7A of the terminal 7 and the thickness of the circuit pattern 2B. One of the blue laser and the near-infrared laser may be irradiated individually. In order to reduce spatter and to obtain a molten portion having a sufficient penetration depth, it is preferable that the blue laser and the near-infrared laser are irradiated simultaneously. The irradiation start times of the two lasers may not be the same, and the two lasers may be simultaneously irradiated within a certain time. For example, after the start of irradiation with the blue laser, irradiation with the near-infrared laser is started later. The near-infrared laser has a high reflectance characteristic with respect to the copper material, that is, the energy absorption rate of the near-infrared laser in the copper material is about several percent and is small. On the other hand, the energy absorption rate of the blue laser in the copper material is 60% or more. When the blue laser is irradiated prior to the near-infrared laser, copper is melted. When the molten copper is irradiated with the near-infrared laser, the energy absorption rate of the near-infrared laser is improved. As a result, energy efficient bonding is realized. In addition, the irradiation shape of the laser, that is, the plane size of the blue laser is larger than that of the near-infrared laser. As a result, the volatilized metal and the like remain in the molten pool, and thus the occurrence of spatter is reduced. In addition, three or more kinds of laser wavelengths may be used. In this case, a laser irradiation time during which lasers of two or more wavelengths are simultaneously irradiated is provided.

During and before and after laser irradiation, an inert gas such as nitrogen (N₂) or argon (Ar) is blown as a shielding gas to the laser irradiation position. In particular, the effect of the shielding gas is remarkable for a copper material that is easily oxidized.

Spatter or fumes are likely to occur in the laser welding process. Therefore, the laser welding is preferably performed before the semiconductor element 4 is mounted on the insulating substrate 2. When the case 6 has heat resistance and can withstand a heating temperature for bonding the semiconductor element 4 and the insulating substrate 2, laser-bonding can be performed before the semiconductor element 4 is mounted on the insulating substrate 2. In other words, when the case 6 can withstand a heating temperature of a heating apparatus such as a reflow apparatus, laser-bonding can be performed before the semiconductor element 4 is mounted on the insulating substrate 2. On the other hand, when laser-bonding is performed after the semiconductor element 4 is mounted on the insulating substrate 2, a cover for protecting the semiconductor element 4 is attached so that spatter and fumes during laser-bonding do not scatter on the semiconductor element 4.

After the laser welding process, when the semiconductor element 4 is not mounted on the insulating substrate 2, the semiconductor element 4 is mounted on the insulating substrate 2 via the bonding material 5. Thereafter, the bonding material 5 is heated by the reflow apparatus to bond the semiconductor element 4 and the circuit pattern 2B. Next, wiring connection of each component in the semiconductor device is performed. Here, each component in the semiconductor device is connected by wiring 8 by a wire bonding apparatus (not illustrated). Next, the space in the case 6 is filled with the sealing resin 9, and each component is sealed. Although not illustrated, a lid may be provided on the upper surface of the sealing resin 9.

### (Effects of Tacking Process and Laser Welding Process)

As illustrated in FIG. 5, the terminal 7 before the tacking process is often not in contact with the insulating substrate 2. As illustrated in FIG. 6, even when the terminal 7 is in contact with the insulating substrate 2, the bonding portion 7A of the terminal 7 is not parallel to the circuit pattern 2B but inclined in many cases. The degree of the deviation is not constant but varies. Therefore, in the laser welding process, when the terminal 7 and the insulating substrate 2 are bonded under the same process condition, the bonding quality varies. In other words, it is difficult to apply the same process conditions.

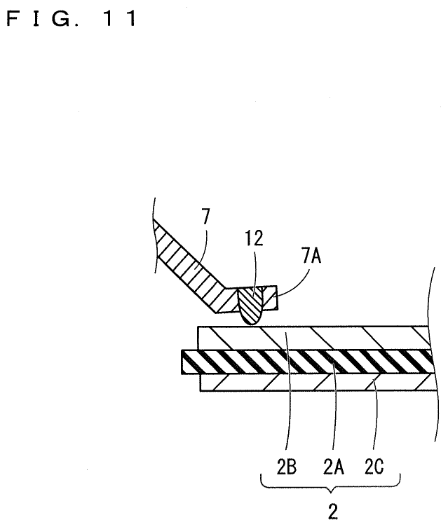

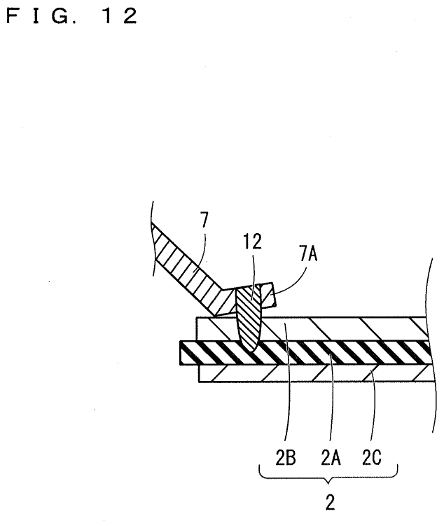

FIGS. 11 and 12 are cross-sectional views illustrating a bonding failure state between the terminal 7 and the insulating substrate 2. FIG. 11 illustrates the bonding portion 7A when the laser welding process is performed in a state where the terminal 7 is not in contact with the insulating substrate 2. When the gap between the bonding portion 7A and the circuit pattern 2B is large, the irradiation energy of the laser is absorbed by the bonding portion 7A and melts the bonding portion 7A, but does not sufficiently reach the circuit pattern 2B. As a result, the circuit pattern 2B is not sufficiently melted, and bonding failure occurs. For example, even after laser irradiation, the bonding portion 7A of the terminal 7 is not bonded to the circuit pattern 2B of the insulating substrate 2. Alternatively, the bonding portion 7A of the terminal 7 is insufficiently bonded to the circuit pattern 2B of the insulating substrate 2. The terminal 7 having such bonding failure is peeled off from the insulating substrate 2 in a process after the laser welding process. FIG. 12 illustrates the bonding portion 7A when the laser welding process is performed with the terminal 7 inclined with respect to the insulating substrate 2. The irradiation energy of the laser passes through the terminal 7 and the circuit pattern 2B and reaches the insulating layer 2A. As a result, the insulating layer 2A is destroyed, and the insulating property of the insulating substrate 2 cannot be secured.

In the method of manufacturing of the first preferred embodiment, the tacking process is performed as described above. In the tacking process, as illustrated in FIG. 7, the tool 13 of the ultrasonic bonding apparatus comes into contact with the surface of the bonding portion 7A. In a state where the tool 13 is in contact with the surface of the bonding portion 7A, a small load and ultrasonic vibration to such an extent that metal burrs and chips are not generated are applied. The back surface of the bonding portion 7A and the circuit pattern 2B of the insulating substrate 2 are solid-phase bonded. The ultrasonic energy at this time is energy that is small enough to perform the tacking. Even when the positional relationship between the terminal 7 and the insulating substrate 2 is as illustrated in FIG. 5 or 6, the bonding portion 7A of the terminal 7 is arranged in parallel to the circuit pattern 2B of the insulating substrate 2 as a result of performing the tacking process.

In addition, as the ultrasonic vibration energy for tacking increases, the bonding portion 7A reliably comes into contact with the circuit pattern 2B. The lower surface of the tool 13 is provided with a cross-shaped or knurled groove so that the terminal 7 can be reliably held and ultrasonic vibration energy can be transmitted. As a result of the tacking process, as illustrated in FIG. 8, the indentation 11 is formed on the surface of the bonding portion 7A as a trace of contact of the tool 13. The indentation 11 is formed by transferring the pattern of grooves of the tool 13. The indentation 11 does not affect the subsequent laser welding process.

After the terminal 7 and the insulating substrate 2 are solid-phase bonded in the tacking process, the terminal 7 is laser-bonded to the circuit pattern 2B in the laser welding process. As illustrated in FIG. 9, the surface of the bonding portion 7A of the terminal 7 is irradiated with a laser beam from an oscillator of a laser apparatus (not illustrated). The bonding portion 7A of the terminal 7 and the surface layer portion of the circuit pattern 2B located below the bonding portion 7A are melted by the irradiation energy of the laser. As a result, the terminal 7 and the circuit pattern 2B are bonded. The laser irradiation energy is controlled to such an extent that appropriate bonding strength is obtained and the insulating layer 2A below the circuit pattern 2B is not destroyed. When the irradiation energy is too large, the insulating layer 2A on the lower side of the circuit pattern 2B is thermally deformed or destroyed resulting in penetration. As a result, insulation as the insulating substrate 2 cannot be secured. Conversely, when the irradiation energy is too small, the melting depth in the surface layer of the circuit pattern 2B becomes shallow. As a result, the bonding strength between the terminal 7 and the circuit pattern 2B becomes insufficient. When a bonding failure occurs, the terminal 7 may be peeled off from the circuit pattern 2B in a manufacturing process after the laser welding process or during operation of the completed semiconductor device.

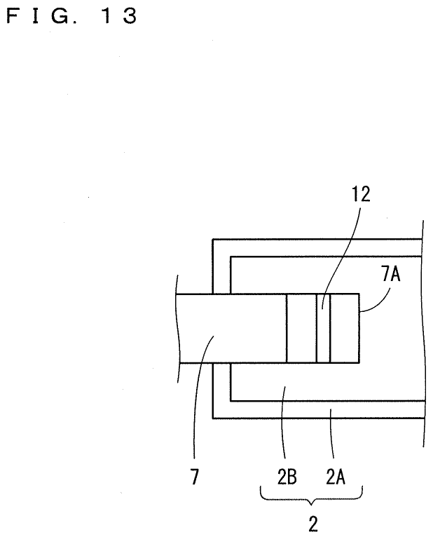

The laser apparatus includes a blue laser oscillator and a near-infrared laser oscillator. Each oscillator can emit a laser of approximately 5 kW or more and 12 kW or less. A laser is scanned by operation of a galvano scanner or a laser head. The melting marks 12 are formed in a line shape by the laser scanning. When the laser irradiation area on the surface of the terminal 7 is smaller than the region where the indentation 11 is formed, as illustrated in FIG. 10, the indentation 11 remains even after the laser irradiation. In other words, the indentation 11 remains in a region where the melting mark 12 is not formed. FIG. 13 is a top view illustrating another configuration of the bonding portion 7A of the terminal 7 and the circuit pattern 2B of the insulating substrate 2. When the indentation 11 formed in the tacking process is shallow, or when the laser irradiation area is larger than the region of the indentation 11, the indentation 11 may not remain.

The bonding portion 7A provided at the end portion of the terminal 7 as described above is solid-phase bonded to the circuit pattern 2B of the insulating substrate 2 by ultrasonic vibration. The bonding portion 7A is arranged in parallel to the circuit pattern 2B by tacking by the solid-phase bonding. In this state, the bonding portion 7A of the terminal 7 is laser-bonded to the circuit pattern 2B. Such a method of manufacturing does not affect the insulating layer 2A of the insulating substrate 2, and makes it possible to stably obtain the bonding portion 7A having high quality and high reliability in a state where insulating properties are secured. The gap between the bonding portion 7A and the circuit pattern 2B after the tacking process can be allowed up to about 0.1 mm. That is, such a gap does not affect the laser welding process.

To summarize the above, the semiconductor device according to the first preferred embodiment includes the circuit pattern 2B and the terminal 7. The circuit pattern 2B is provided on the upper surface of the insulating layer 2A and is electrically connected to the semiconductor element 4. The terminal 7 includes the bonding portion 7A bonded to the circuit pattern 2B, and can be connected to an external circuit. The bonding portion 7A includes a region solid-phase bonded to the circuit pattern 2B and a region laser-bonded thereto.

Such a semiconductor device realizes stable laser-bonding and has high reliability. Not only the bonding strength is secured, but also wiring connection having high quality and high reliability is realized.

The method of manufacturing the semiconductor device according to the first preferred embodiment includes the processes of: preparing the circuit pattern 2B provided on the upper surface of the insulating layer 2A and the terminal 7 connectable to the external circuit; and bonding the bonding portion 7A of the terminal 7 to the circuit pattern 2B. The process of bonding the bonding portion 7A to the circuit pattern 2B includes a tacking process of solid-phase bonding the bonding portion 7A to the circuit pattern 2B, and a laser welding process of laser-bonding the bonding portion 7A to the circuit pattern 2B after the tacking process.

Such a method of manufacturing realizes stable laser-bonding and enables manufacturing of a semiconductor device having high reliability. Not only the bonding strength is secured, but also wiring connection having high quality and high reliability is realized. During mass production of semiconductor devices, a production process of laser welding is stabilized. In addition, the number of insulation-defective products is reduced. The bonding state between the terminal 7 and the insulating substrate 2 of the first preferred embodiment realizes high reliability and high quality of the semiconductor device.

A semiconductor device on which the semiconductor element 4 for converting power is mounted is referred to as a power semiconductor device. Application areas of power semiconductor devices are spreading not only in consumer applications but also in industrial equipment applications, automobile applications, railway applications, and the like. As the application area is enlarged, the current capacity flowing in the semiconductor device increases. In addition, the semiconductor device is mounted in a severe environment such as in an engine room in the case of automobile use, or under the floor in the case of railway use. The semiconductor device is required to have high reliability and a long lifetime so as to be adaptable to such an environment. The wiring connection in the semiconductor device is an important element for realizing the characteristics of high reliability and a long lifetime.

A gap is likely to be generated between the end portion of the terminal 7 and the insulating substrate 2, and a point contact is often formed. Even when a jig is used at the time of laser welding, when the thickness of the terminal 7 is 1.0 mm or more, there is a limit to correction due to rigidity of the terminal 7. Further, in a situation where the surface of the terminal 7 is irradiated with a laser beam, it is very difficult to bring the terminal 7 pressed against the insulating substrate 2 by the jig into contact with the insulating substrate 2 and hold the terminal 7 in parallel. In addition, the insulating layer 2A in the insulating substrate 2 is brittle. There is a limit to the pressurization control of the terminal 7 so that the insulating layer 2A is not damaged. The semiconductor device of the first preferred embodiment solves such a problem.

In the semiconductor device of the first preferred embodiment, two semiconductor elements 4 are mounted. The number of semiconductor elements 4 is not limited to two. A necessary number of semiconductor elements 4 are mounted according to specifications of the semiconductor device. For example, when a semiconductor device is incorporated in an inverter circuit, the semiconductor device has a so-called 2-in-1 configuration having an upper arm and a lower arm. In addition, the semiconductor device may have a 1-in-1 configuration or a 6-in-1 configuration. That is, at least one semiconductor element 4 is mounted.

### Second Preferred Embodiment

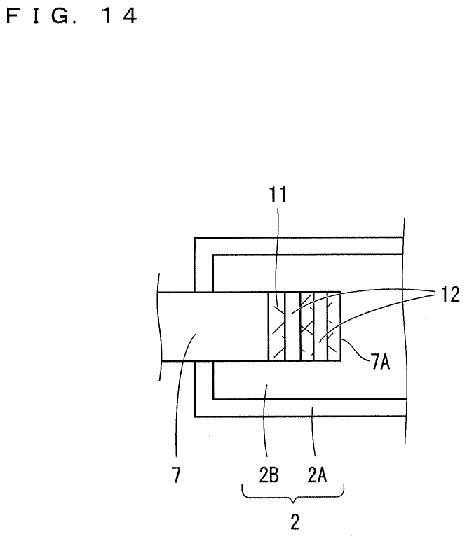

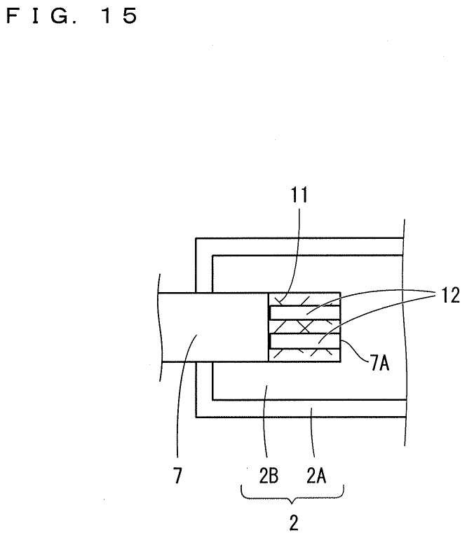

FIGS. 14 and 15 are top views illustrating a configuration of a bonding portion 7A of the terminal 7 in a second preferred embodiment. A plurality of line-shaped melting marks 12 may be provided. The extending direction of the melting mark 12 is not limited. The extending direction is, for example, a longitudinal direction, a lateral direction, an oblique direction, or a combination thereof on the surface of the bonding portion 7A. For example, two lines may intersect. The number and direction of the lines are determined according to the area and shape of the laser-bonding point.

Since the melting mark 12 has such a configuration, stable bonding strength is secured. In addition, since a current area is secured, a semiconductor device capable of flowing a large current is provided.

### Third Preferred Embodiment

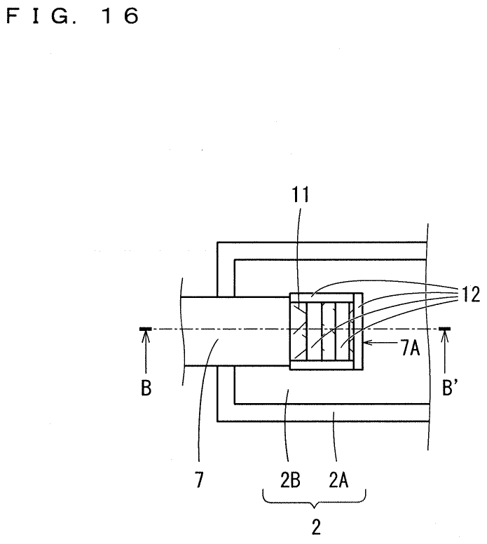

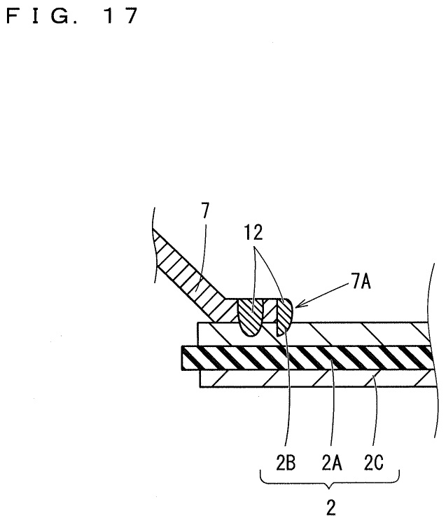

FIG. 16 is a top view illustrating a configuration of a bonding portion 7A of the terminal 7 in a third preferred embodiment. FIG. 17 is a cross-sectional view illustrating another example of the configuration of the bonding portion 7A of the terminal 7. FIG. 17 illustrates a cross section taken along line B-B′ in FIG. 16. Two melting marks 12 extend in the longitudinal direction on the surface of the bonding portion 7A. The melting mark 12 is also formed on the outer peripheral portion of the bonding portion 7A. The melting mark 12 formed on the outer peripheral portion is a fillet welded portion. In the manufacturing process, the laser is applied not only to the surface of the bonding portion 7A of the terminal 7 but also to the outer peripheral portion of the bonding portion 7A. Accordingly, the fillet welded portion is formed.

With such a configuration, the bonding strength is improved and the bonding area is increased. A semiconductor device capable of flowing a large current is realized.

### Fourth Preferred Embodiment

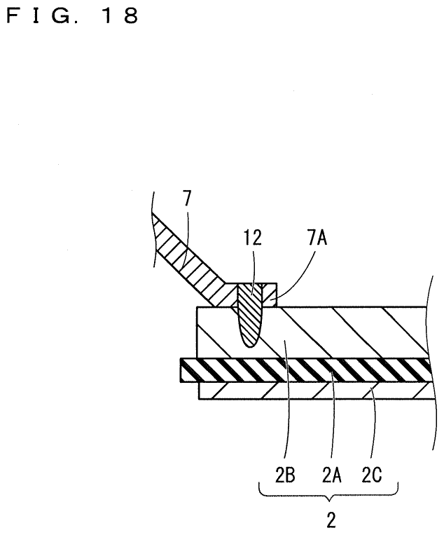

FIG. 18 is a cross-sectional view illustrating a configuration of a bonding portion 7A of the terminal 7 in a fourth preferred embodiment. The thickness of the circuit pattern 2B is larger than the thickness of the heat dissipation layer 2C. The thickness of the circuit pattern 2B is about 0.5 mm or more and 2.0 mm or less.

When the thickness of the circuit pattern 2B is large, laser irradiation energy is less likely to be transmitted to the insulating layer 2A. Therefore, damage to the insulating layer 2A is reduced, and insulation of the insulating substrate 2 is secured even after laser-bonding. In addition, the resistance and inductance of the semiconductor device are reduced, and a semiconductor device suitable for high-current is realized.

### Fifth Preferred Embodiment

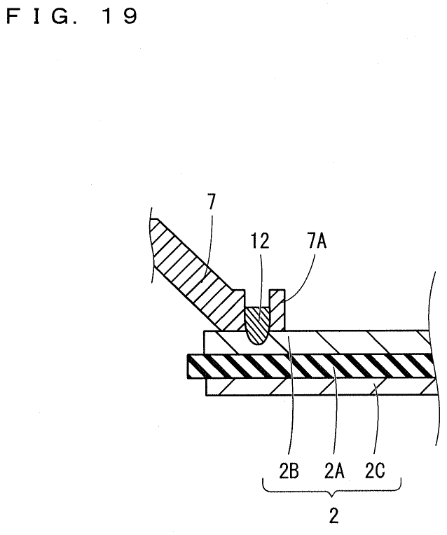

FIG. 19 is a cross-sectional view illustrating a configuration of a bonding portion 7A of the terminal 7 in a fifth preferred embodiment. The thickness of the bonding portion 7A in the melting mark 12 is thinner than the thickness of the bonding portion 7A around the melting mark 12. The melting mark 12 is recessed on the surface of the bonding portion 7A. In the tacking process, the tool 13 presses the surface of the bonding portion 7A of the terminal 7. As a result, the indentation 11 is formed, and the thickness of the region where the indentation 11 is formed is reduced to about half the thickness around the indentation 11. In the laser welding process, the indentation 11 in which the terminal 7 is thinned is irradiated with the laser beam. The indentation 11 does not affect laser irradiation. The melting mark 12 is formed by laser irradiation, and the thickness of the region where the melting mark 12 is formed is smaller than the thickness of the bonding portion 7A around the melting mark 12.

In general, when the thickness of the terminal 7 is larger than the thickness of the circuit pattern 2B, laser welding is difficult. However, when the tool 13 in the tacking process reduces the thickness of a part of the terminal 7, laser welding becomes easier. For example, even when the thickness of the bonding portion 7A of the terminal 7 is 1.5 mm or more, the laser welding can be easily performed without damaging the insulating layer 2A under the circuit pattern 2B. As a result, stable laser-bonding is realized. In addition, the resistance and inductance of the semiconductor device are reduced, and a semiconductor device suitable for high-current is realized.

### Sixth Preferred Embodiment

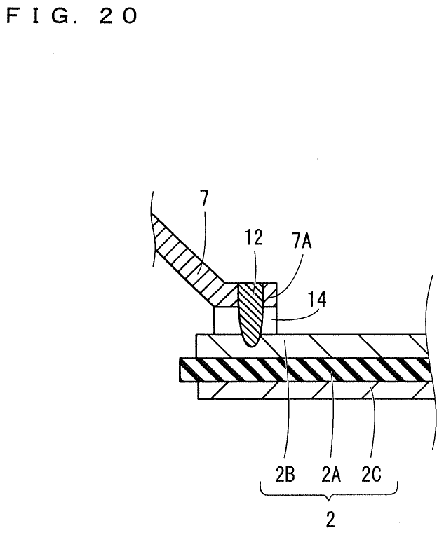

FIG. 20 is a cross-sectional view illustrating a configuration of a bonding portion 7A of the terminal 7 in a sixth preferred embodiment. A metal sheet 14 is provided between the back surface of the bonding portion 7A and the circuit pattern 2B. The terminal 7 is bonded to the circuit pattern 2B via the metal sheet 14. The metal sheet 14 is made of copper or aluminum. The thickness of the metal sheet 14 is about 0.1 mm or more and 1.0 mm or less.

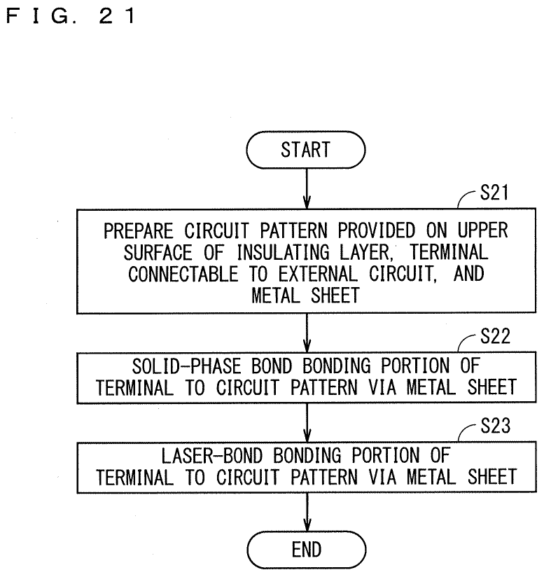

FIG. 21 is a flowchart illustrating a method of manufacturing a semiconductor device in the sixth preferred embodiment.

In step S21, the circuit pattern 2B provided on the upper surface of the insulating layer 2A, the terminal 7 connectable to an external circuit, and the metal sheet 14 are prepared. Here, the insulating substrate 2 is prepared as the circuit pattern 2B. Next, the bonding portion 7A of the terminal 7 is disposed on the circuit pattern 2B via the metal sheet 14. The position of the terminal 7 is determined using a dedicated jig (not illustrated) as necessary.

In step S22, the bonding portion 7A of the terminal 7 is solid-phase bonded to the circuit pattern 2B via the metal sheet 14. Similarly to the first preferred embodiment, the tool 13 of the ultrasonic bonding apparatus comes into contact with the surface of the bonding portion 7A of the terminal 7 and a load is applied thereto. In this state, ultrasonic energy is applied from the tool 13, and the terminal 7, the metal sheet 14, and the insulating substrate 2 are solid-phase bonded to each other. The bonding strength is sufficient to the extent that the tack state can be maintained, and in such a tacking process, metal burrs and chips are not generated.

In step S23, the bonding portion 7A of the terminal 7 is laser-bonded to the circuit pattern 2B via the metal sheet 14. The metal sheet 14 functions as a thermal buffer. In addition, the metal sheet 14 prevents the irradiation energy of the laser from being transmitted to the insulating layer 2A. Therefore, the insulating layer 2A is not damaged.

The metal sheet 14 may protrude from the terminal 7 when the semiconductor device is viewed from above, that is, in plan view. The productivity of the tacking process is improved. The number of metal sheets 14 is not limited to one, and a plurality of metal sheets 14 may be provided. That is, since at least one metal sheet 14 is provided between the back surface of the bonding portion 7A and the circuit pattern 2B, the above effect is produced.

### Seventh Preferred Embodiment

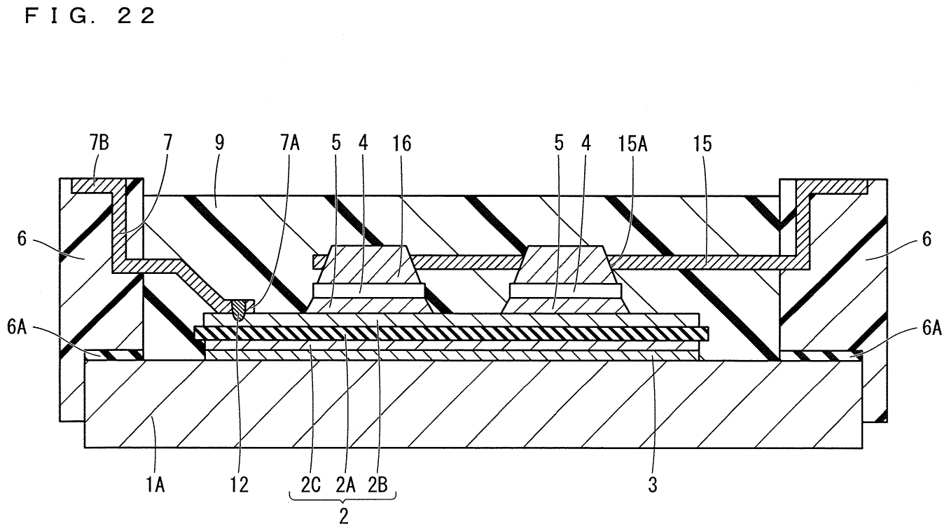

FIG. 22 is a cross-sectional view illustrating a configuration of a semiconductor device in a seventh preferred embodiment. Description of the same configuration as that of the first preferred embodiment will be omitted. The semiconductor device includes an electrode 15 instead of the wiring 8. The electrode 15 is bonded to the top electrode of the semiconductor element 4 via the bonding material 16. The bonding material 16 is a solder material or a sintered material. Similarly to the terminal 7, the electrode 15 is fixed to the case 6 in a state where a part of the electrode 15 is inserted into the case 6. The electrode 15 is configured to be connectable to an external circuit. Similarly to the terminal 7, the electrode 15 is formed by processing a metal flat plate into a predetermined shape. In other words, the electrode 15 has a plate shape and includes a bent portion. The electrode 15 is made of, for example, copper. The electrode 15 includes a through hole 15A at a bonding point with the semiconductor element 4. The semiconductor element 4 is bonded to the electrode 15 via the bonding material 16 filled in the through hole 15A.

In the seventh preferred embodiment, components such as the semiconductor element 4 are connected by one plate-shaped electrode 15. Therefore, an internal wiring structure having higher strength and higher reliability than the wiring 8 can be obtained. Such a configuration is suitable for a semiconductor device in which a large current flows.

In addition, the semiconductor element 4 and the electrode 15 are bonded by the bonding material 16 filled in the through hole 15A. Therefore, the bonding strength is secured, and the stress applied to the bonding point is relaxed. As a result, a semiconductor device having a long lifetime and high reliability is realized.

Any one of the configurations described in the first to sixth preferred embodiments is applied to the bonding configuration between the bonding portion 7A of the terminal 7 and the circuit pattern 2B.

### Eighth Preferred Embodiment

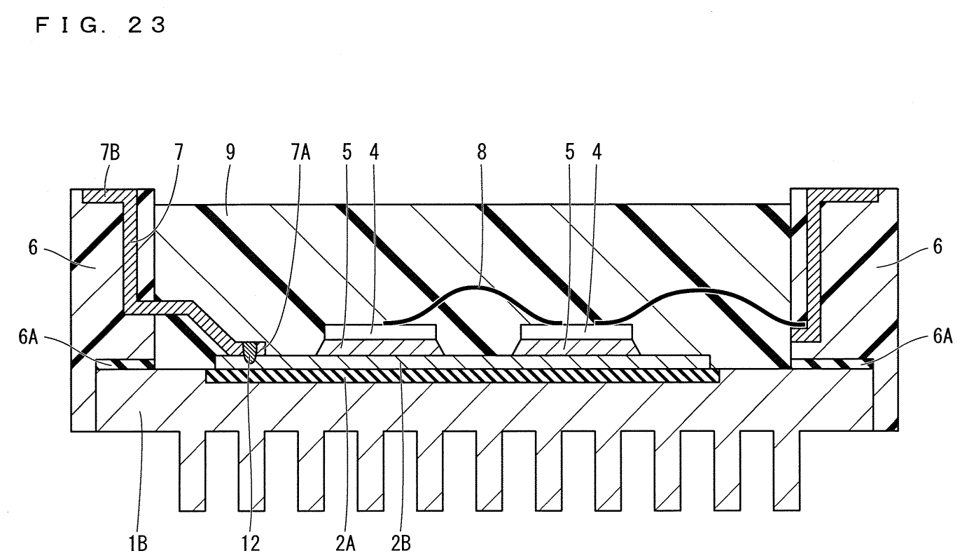

FIG. 23 is a cross-sectional view illustrating a configuration of a semiconductor device according to an eighth preferred embodiment. Description of the same configuration as that of the first preferred embodiment will be omitted. The semiconductor device includes a cooler 1B instead of the cooler 1A of the first preferred embodiment. The cooler 1B includes a plurality of fins. The heat dissipation is improved by the plurality of fins. The cooler 1B is made of metal having excellent thermal conductivity, such as copper or aluminum. The cooler 1B may have a configuration applicable to a water cooling system in which a refrigerant flows between fins.

The insulating layer 2A is provided on one surface of the cooler 1B integrally with the cooler 1B. The circuit pattern 2B is provided on the insulating layer 2A. The insulating layer 2A and the circuit pattern 2B are integrated with the cooler 1B, in other words, the cooler 1B is an insulating layer-integrated cooler. The insulating layer 2A is formed of, for example, an epoxy resin or a ceramic material.

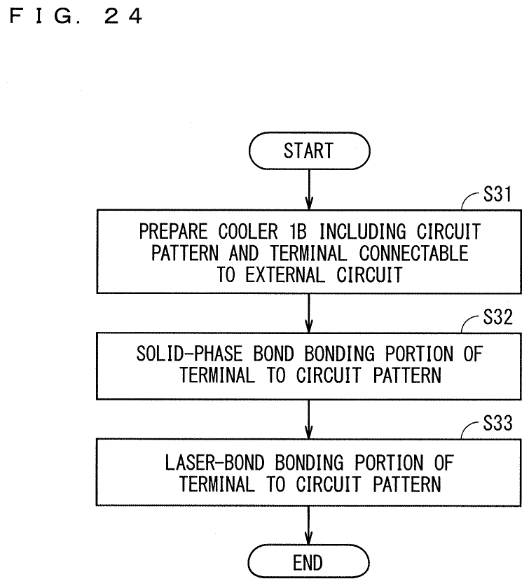

FIG. 24 is a flowchart illustrating a method of manufacturing a semiconductor device in the eighth preferred embodiment.

In step S31, the cooler 1B including the circuit pattern 2B and the terminal 7 connectable to an external circuit are prepared. Next, the bonding portion 7A of the terminal 7 is disposed on the circuit pattern 2B integrated with the cooler 1B. The position of the terminal 7 is determined using a dedicated jig (not illustrated) as necessary.

In step S32, the bonding portion 7A of the terminal 7 is solid-phase bonded to the circuit pattern 2B. As a result, the back surface of the bonding portion 7A is tacked to the circuit pattern 2B.

In step S33, the bonding portion 7A of the terminal 7 is laser-bonded to the circuit pattern 2B.

In such a semiconductor device, the number of components between semiconductor element 4 and cooler 1B is reduced as compared with the first preferred embodiment. Therefore, the thermal resistance is also reduced, and the cooling efficiency is improved. In addition, man-hours in the manufacturing process are reduced, and the production cost is reduced. The semiconductor device is reduced in size and weight.

Any one of the configurations described in the first to fifth preferred embodiments is applied to the bonding configuration between the bonding portion 7A of the terminal 7 and the circuit pattern 2B.

As in the sixth preferred embodiment, the metal sheet 14 may be provided between the back surface of the bonding portion 7A and the circuit pattern 2B. In this case, the terminal 7 is bonded to the circuit pattern 2B via the metal sheet 14.

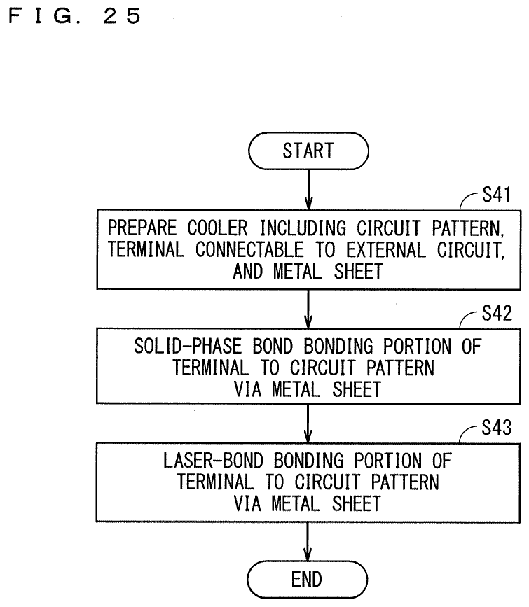

FIG. 25 is a flowchart illustrating a method of manufacturing in a case where the metal sheet 14 is provided.

In step S41, the cooler 1B including the circuit pattern 2B, the terminal 7 connectable to an external circuit, and the metal sheet 14 are prepared. Next, the bonding portion 7A of the terminal 7 is disposed on the circuit pattern 2B via the metal sheet 14. If necessary, the position of the terminal 7 is determined using a dedicated jig.

In step S42, the bonding portion 7A of the terminal 7 is solid-phase bonded to the circuit pattern 2B via the metal sheet 14.

In step S43, the bonding portion 7A of the terminal 7 is laser-bonded to the circuit pattern 2B via the metal sheet 14.

With such a configuration, improvement in cooling efficiency, reduction in production cost, and reduction in size and weight of the semiconductor device can be realized. The metal sheet 14 prevents damage to the insulating layer 2A in the laser welding process.

### Ninth Preferred Embodiment

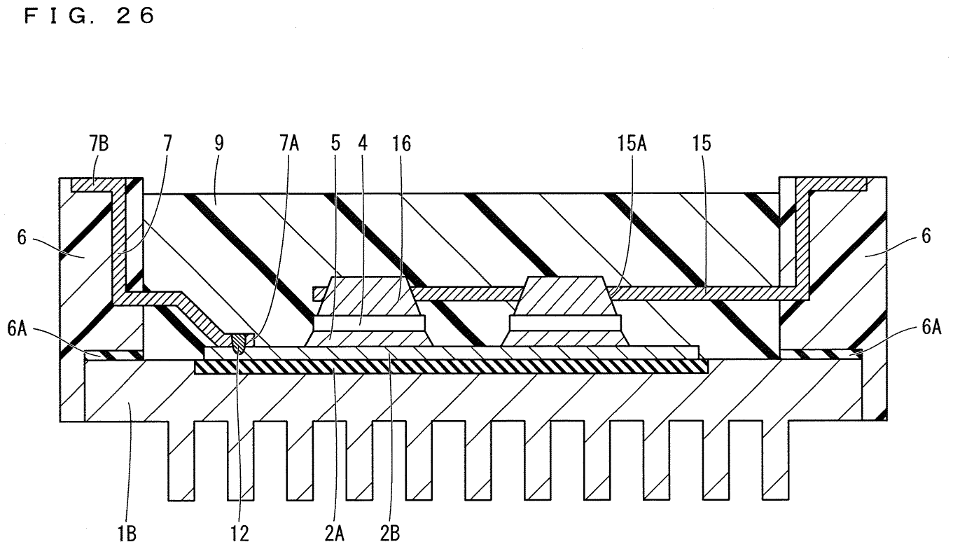

FIG. 26 is a cross-sectional view illustrating a configuration of a semiconductor device according to a ninth preferred embodiment. The semiconductor device includes an electrode 15 instead of the wiring 8. Description of the same configuration as that of the first preferred embodiment will be omitted. The electrode 15 is bonded to the top electrode of the semiconductor element 4 via the bonding material 16. The bonding material 16 is a solder material or a sintered material. Similarly to the terminal 7, the electrode 15 is fixed to the case 6 in a state where a part of the electrode 15 is inserted into the case 6. The electrode 15 is configured to be connectable to an external circuit. Similarly to the terminal 7, the electrode 15 is formed by processing a metal flat plate into a predetermined shape. In other words, the electrode 15 has a plate shape and includes a bent portion. The electrode 15 is made of, for example, copper. The electrode 15 includes a through hole 15A at a bonding point with the semiconductor element 4. The semiconductor element 4 is bonded to the electrode 15 via the bonding material 16 filled in the through hole 15A.

In the ninth preferred embodiment, components such as the semiconductor element 4 are connected by one flat-plate-like electrode 15. Therefore, an internal wiring structure having higher strength and higher reliability than the wiring 8 can be obtained. Such a configuration is suitable for a semiconductor device in which a large current flows.

In addition, the semiconductor element 4 and the electrode 15 are bonded by the bonding material 16 filled in the through hole 15A. Therefore, the bonding strength is secured, and the stress applied to the bonding point is relaxed. As a result, a semiconductor device having a long lifetime and high reliability is realized.

Any one of the configurations of the first to sixth preferred embodiments is applied to the bonding configuration between the bonding portion 7A of the terminal 7 and the circuit pattern 2B.

### Tenth Preferred Embodiment

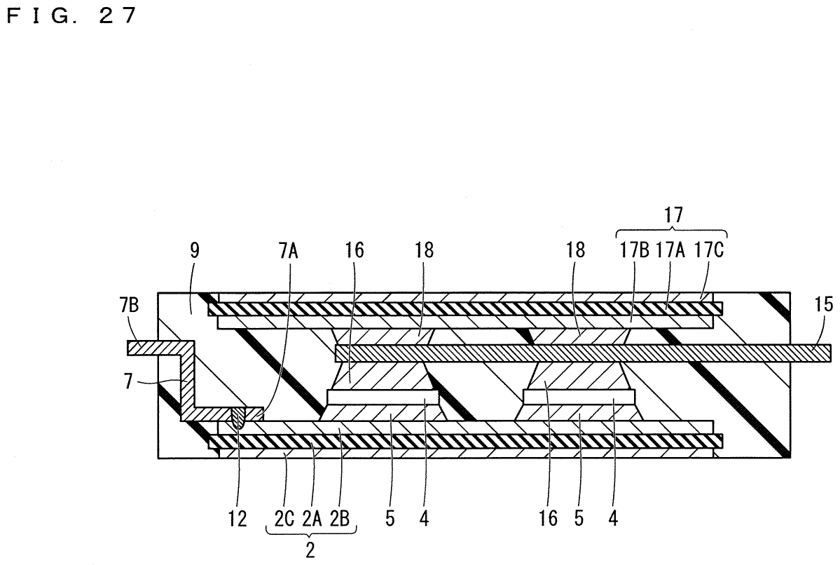

FIG. 27 is a cross-sectional view illustrating a configuration of a semiconductor device in a tenth preferred embodiment. The semiconductor device includes an insulating substrate 2, a semiconductor element 4, a bonding material 5, a terminal 7, a sealing resin 9, an electrode 15, a bonding material 16, an insulating substrate 17, and a bonding material 18. Description of the same configuration as that of the first preferred embodiment will be omitted.

The insulating substrate 17 is provided above the semiconductor element 4. The insulating substrate 17 has the same configuration as the insulating substrate 2 provided below the semiconductor element 4. The insulating substrate 17 includes an insulating layer 17A, a circuit pattern 17B, and a heat dissipation layer 17C.

The sealing resin 9 is a mold resin. In other words, in the manufacturing process of the semiconductor device, each component is resin-sealed by a transfer molding method. The heat dissipation layer 2C and the heat dissipation layer 17C are exposed from the mold resin, and the semiconductor device has a so-called double-sided cooling structure.

The mold resin contains a thermosetting epoxy resin as a main component. However, the material of the mold resin is not limited to the epoxy resin. The mold resin may be a thermosetting resin having a required elastic modulus, adhesion, heat resistance, and insulation property depending on the external size and internal structure of the semiconductor device. For example, the mold resin may be a silicone resin, a phenol resin, a polyimide resin, or the like.

The mold resin may contain fine particles or fillers for securing strength and thermal conductivity and improving heat dissipation of the semiconductor element 4. The fine particles and the filler are made of, for example, a ceramic material. The ceramic material is, for example, alumina, aluminum nitride, silicon nitride, silicon dioxide (SiO₂), boron nitride (BN), diamond, silicon carbide, or boron oxide (B₂O₃).

The electrode 15 is bonded to the top electrode of the semiconductor element 4 via a bonding material 16, and is bonded to the circuit pattern 17B of the insulating substrate 17 via a bonding material 18. An end portion of the electrode 15 is exposed from the mold resin and is configured to be connectable to an external circuit. The thickness of the electrode 15 is about 1 mm. The bonding material 16 and the bonding material 18 are any of the materials of the bonding material 5 illustrated in the first preferred embodiment.

The top electrode of semiconductor element 4 is made of gold or copper. When bonding material 16 is a sintered material containing silver particles, the top electrode of semiconductor element 4 may be formed of silver.

Any one of the configurations of the first to sixth preferred embodiments is applied to the bonding configuration between the bonding portion 7A of the terminal 7 and the circuit pattern 2B.

Such a semiconductor device has a double-sided cooling structure, and thus has excellent heat dissipation of the semiconductor element 4. In addition, since the semiconductor element 4 is packaged with the mold resin, productivity is excellent.

### Eleventh Preferred Embodiment

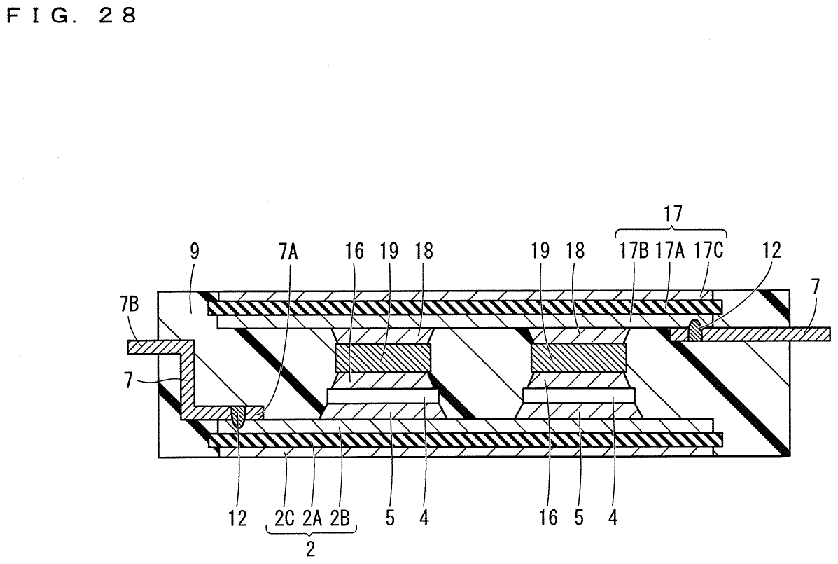

FIG. 28 is a cross-sectional view illustrating a configuration of a semiconductor device in an eleventh preferred embodiment. The semiconductor device includes an insulating substrate 2, a semiconductor element 4, a bonding material 5, a terminal 7, a sealing resin 9, a bonding material 16, an insulating substrate 17, a bonding material 18, and a heat dissipation plate 19. In the eleventh preferred embodiment, two terminals 7 are provided. Description of the same configuration as that of the first preferred embodiment will be omitted.

The insulating substrate 17 and the sealing resin 9 have the same configuration as in the tenth preferred embodiment. The insulating substrate 17 is provided above the semiconductor element 4, and the sealing resin 9 is a mold resin.

The heat dissipation plate 19 has a plate shape or a block shape and is formed of metal containing copper. The heat dissipation plate 19 is bonded to the top electrode of semiconductor element 4 via bonding material 16, and bonded to circuit pattern 17B of insulating substrate 17 via bonding material 18. Based on the difference in linear expansion coefficient between the semiconductor element 4 and the insulating substrate 2, the heat dissipation plate 19 may be formed of tungsten, molybdenum, or an alloy thereof. The heat dissipation plate 19 may be larger in size than the semiconductor element 4 in planar view.

One of the two terminals 7 is bonded to the circuit pattern 2B of the insulating substrate 2 provided below the semiconductor element 4 as in any one of the first to tenth preferred embodiments. The other of the two terminals 7 is bonded to the circuit pattern 17B of the insulating substrate 17 provided above the semiconductor element 4. The bonding portion 7A bonded to the insulating substrate 17 also includes a region solid-phase bonded to the circuit pattern 17B and a region laser-bonded thereto.

Any one of the configurations of the first to sixth preferred embodiments is applied to the bonding configuration between the bonding portion 7A of the terminal 7 and the circuit pattern 2B. Similarly, any one of the configurations of the first to sixth preferred embodiments is applied to the bonding configuration between the bonding portion 7A of the terminal 7 and the circuit pattern 17B. With such a configuration, the heat dissipation of the semiconductor element 4 is further improved. In addition, since the semiconductor element 4 is sealed with the mold resin, assemblability is excellent.

Although not illustrated, a through hole may be provided in the heat dissipation plate 19. In this case, semiconductor element 4 is bonded to heat dissipation plate 19 via bonding material 16 filled in the through hole. With such a configuration, since the stress at the bonding point is relaxed, a bonding point having a long lifetime and high reliability can be obtained.

### Twelfth Preferred Embodiment

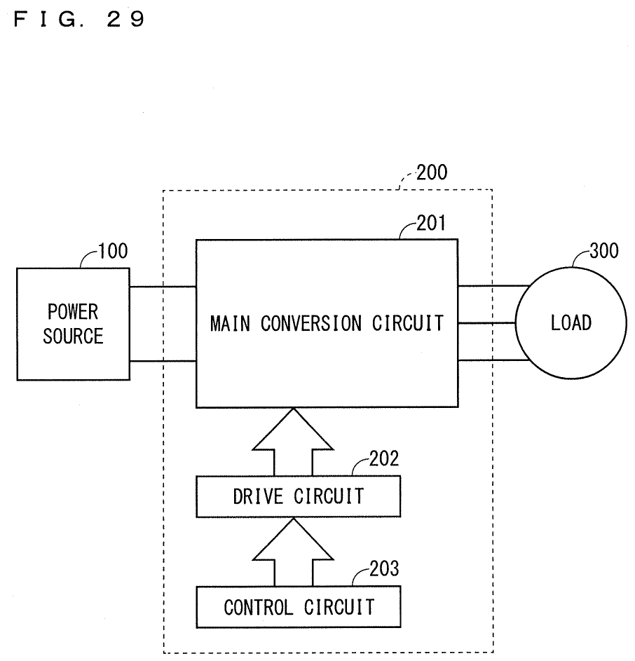

FIG. 29 is a functional block diagram illustrating a configuration of a power conversion system according to a twelfth preferred embodiment. The power conversion system includes a power source 100, a power conversion apparatus 200, and a load 300.

The power source 100 is a DC power source. The power source 100 supplies DC power to the power conversion apparatus 200. The power source 100 is, for example, a DC system, a solar cell, a storage battery, or the like. The power source 100 may be a DC/DC converter that converts DC power output from the DC system into predetermined power. The power source 100 may be a rectifier circuit, an AC/DC converter, or the like connected to an AC system.

The power conversion apparatus 200 is connected to the power source 100 and the load 300. The power conversion apparatus 200 in the twelfth preferred embodiment is a three-phase inverter. The power conversion apparatus 200 converts DC power supplied from the power source 100 into AC power. The power conversion apparatus 200 supplies the AC power to the load 300.

The load 300 is driven by the AC power supplied from the power conversion apparatus 200. The load 300 in the twelfth preferred embodiment is a three-phase motor. The three-phase motor is not limited to a specific application. The three-phase motor is mounted on various electric devices. The three-phase motor is mounted on, for example, a hybrid vehicle, an electric vehicle, a railway vehicle, an elevator, an air conditioning device, or the like.

Hereinafter, details of the power conversion apparatus 200 will be described. The power conversion apparatus 200 includes a main conversion circuit 201, a drive circuit 202, and a control circuit 203.

The main conversion circuit 201 includes the semiconductor device according to any one of the first to eleventh preferred embodiments. The semiconductor device constitutes a two-level three-phase full-bridge circuit (not illustrated). The three-phase full-bridge circuit includes six switching elements (not illustrated) and six freewheeling diodes (not illustrated). At least one element of the switching element and the freewheeling diode corresponds to the semiconductor element 4 included in the semiconductor device according to any one of the first to eleventh preferred embodiments.

The three-phase full-bridge circuit includes three upper arms and three lower arms. Each of the upper arm and the lower arm includes one switching element and one freewheeling diode connected in anti-parallel to the switching element. In addition, the switching element included in one upper arm is connected in series to the switching element included in one lower arm, and they constitute a set of upper and lower arms. That is, the three-phase full-bridge circuit includes three sets of upper and lower arms. The three sets of upper and lower arms correspond to the U phase, the V phase, and the W phase of the three-phase full-bridge circuit, respectively. The output terminals of the three sets of upper and lower arms, that is, the three output terminals of the main conversion circuit 201 are connected to the load 300.

The main conversion circuit 201 converts DC power supplied from the power source 100 into AC power by switching operation of the switching element. The main conversion circuit 201 supplies the AC power to the load 300 via the output terminal.

The drive circuit 202 generates a drive signal for driving the switching element of the main conversion circuit 201 according to a control signal output from the control circuit 203. The drive circuit 202 supplies the drive signal to the control electrode of the switching element of the main conversion circuit 201.

The drive signal is a signal for turning on the switching element or a signal for turning off the switching element. More specifically, the drive signal in a case where the switching element is maintained in the ON state is a voltage signal (ON signal) equal to or higher than the threshold voltage of the switching element. The drive signal when the switching element is maintained in the OFF state is a voltage signal (OFF signal) smaller than the threshold voltage of the switching element.

The control circuit 203 outputs a control signal for controlling the drive circuit 202 to the drive circuit 202. At that time, the control circuit 203 calculates a time (ON time) during which each switching element of the main conversion circuit 201 is to be turned on based on the power to be supplied to the load 300, and generates a control signal. That is, the control circuit 203 generates a control signal so that the main conversion circuit 201 is subjected to pulse width modulation (PWM) control. The control circuit 203 outputs a control signal to the drive circuit 202 so as to output an ON signal to the switching element that is to be turned on and an OFF signal to the switching element that is to be turned off. In this manner, the control circuit 203 controls the switching elements of the main conversion circuit 201 such that predetermined power is supplied to the load 300.

Since the semiconductor device according to any one of the first to eleventh preferred embodiments is applied to the switching element of the main conversion circuit 201 in the twelfth preferred embodiment, reliability is improved.

In the twelfth preferred embodiment, an example in which the power conversion apparatus 200 is a two-level three-phase inverter has been described, but the configuration of the power conversion apparatus 200 is not limited thereto. For example, the power conversion apparatus 200 may be a multi-level power conversion apparatus such as a three-level power conversion apparatus. Alternatively, the power conversion apparatus 200 may be a single-phase inverter for supplying power to a single-phase load. When the load 300 is a DC load, the power conversion apparatus 200 may be a DC/DC converter or an AC/DC converter. When the load 300 is a solar power generation system, a power storage system, or the like, the power conversion apparatus 200 may be a power conditioner.

In the twelfth preferred embodiment, an example in which the load 300 is a three-phase motor has been described, but the configuration of the load 300 is not limited thereto. For example, the load 300 may be an electrical discharge machine, a laser machine, an induction heating cooker, or a contactless power delivery system.

In the present disclosure, the preferred embodiments can be freely combined, and the preferred embodiments can be appropriately modified or omitted.

Hereinafter, various aspects of the present disclosure will be collectively described as appendices.

### (Appendix 1)

A semiconductor device comprising:
a circuit pattern provided on an upper surface of an insulating layer and electrically connected to a semiconductor element; and
a terminal including a bonding portion bonded to the circuit pattern and connectable to an external circuit,
wherein the bonding portion includes a region solid-phase bonded to the circuit pattern and a region laser-bonded thereto.

### (Appendix 2)

The semiconductor device according to Appendix 1, wherein the bonding portion includes an indentation formed on a surface of the bonding portion, which is a surface opposite to a back surface of the bonding portion bonded to the circuit pattern, in the region subjected to the solid-phase bonding.

### (Appendix 3)

The semiconductor device according to Appendix 1 or 2, wherein the bonding portion includes a melting mark formed on the surface of the bonding portion in the laser-bonded region.

### (Appendix 4)

The semiconductor device according to Appendix 3, wherein the indentation is formed around the melting mark on the surface of the bonding portion, and is not formed inside the melting mark on the surface of the bonding portion.

### (Appendix 5)

The semiconductor device according to Appendix 3, wherein the melting mark is formed from the surface of the bonding portion to a surface layer of the circuit pattern in a thickness direction of the bonding portion.

### (Appendix 6)

The semiconductor device according to Appendix 3, wherein the melting mark is formed in a line shape on the surface of the bonding portion.

### (Appendix 7)

The semiconductor device according to Appendix 3, wherein the melting mark is formed on an outer peripheral portion of the bonding portion.

### (Appendix 8)

The semiconductor device according to Appendix 3, wherein a thickness of the bonding portion in the melting mark is thinner than a thickness of the bonding portion around the melting mark.

### (Appendix 9)

The semiconductor device according to any one of Appendices 1 to 8, further comprising at least one metal sheet provided between the back surface of the bonding portion and the circuit pattern,
wherein the terminal is bonded to the circuit pattern via the at least one metal sheet.

### (Appendix 10)

The semiconductor device according to any one of Appendices 1 to 9, further comprising an insulating substrate including the insulating layer and the circuit pattern,
wherein the bonding portion of the terminal is arranged in parallel to the circuit pattern.
   (appendix 11)

The semiconductor device according to any one of Appendices 1 to 10, further comprising a cooler,
wherein the insulating layer is provided integrally with the cooler on one surface of the cooler, and
the bonding portion of the terminal is disposed parallel to the circuit pattern.

### (Appendix 12)

The semiconductor device according to any one of Appendices 1 to 11, further comprising: an electrode having a plate shape and connectable to the external circuit,
wherein a bottom electrode of the semiconductor element is bonded to the circuit pattern, and
a top electrode of the semiconductor element is bonded to the electrode.

### (Appendix 13)

The semiconductor device according to Appendix 12, wherein
the electrode includes a through hole, and
the semiconductor element is bonded to the electrode via a bonding material filled in the through hole.

### (Appendix 14)

The semiconductor device according to any one of Appendices 1 to 13, further comprising a heat dissipation plate having a plate shape or a block shape,
wherein a bottom electrode of the semiconductor element is bonded to the circuit pattern, and
a top electrode of the semiconductor element is bonded to the heat dissipation plate.

### (Appendix 15)

The semiconductor device according to Appendix 14, wherein
the heat dissipation plate includes a through hole, and
the semiconductor element is bonded to the heat dissipation plate via a bonding material filled in the through hole.

### (Appendix 16)

The semiconductor device according to any one of Appendices 1 to 15, further comprising a heat dissipation layer provided on a lower surface of the insulating layer,
wherein a thickness of the circuit pattern is thicker than a thickness of the heat dissipation layer.

### (Appendix 17)

The semiconductor device according to any one of Appendices 1 to 16, wherein the insulating layer is formed of any one of a ceramic material and a resin.

### (Appendix 18)

The semiconductor device according to any one of Appendices 1 to 17, wherein the semiconductor element is an RC-IGBT.

### (Appendix 19)

The semiconductor device according to any one of Appendices 1 to 18, wherein the semiconductor element is formed of a wide band gap semiconductor.

### (Appendix 20)

A method of manufacturing a semiconductor device, the method comprising:
a process of preparing a circuit pattern provided on an upper surface of an insulating layer and a terminal connectable to an external circuit; and
a process of bonding a bonding portion of the terminal to the circuit pattern,
wherein
the process of bonding the bonding portion of the terminal to the circuit pattern includes
   a tacking process of solid-phase bonding the bonding portion of the terminal to the circuit pattern, and
   a laser welding process of laser-bonding the bonding portion of the terminal to the circuit pattern after the tacking process.

### (Appendix 21)

The method of manufacturing a semiconductor device according to Appendix 20, wherein
the laser welding process includes:
   irradiating a surface of the bonding portion opposite to a back surface of the bonding portion tacked to the circuit pattern by the solid-phase bonding with a laser to laser-bond the bonding portion to the circuit pattern.

### (Appendix 22)

The method of manufacturing a semiconductor device according to Appendix 20 or 21, wherein
the tacking process includes:
   solid-phase bonding the bonding portion to the circuit pattern via at least one metal sheet provided between the back surface of the bonding portion and the circuit pattern.

### (Appendix 23)

The method of manufacturing a semiconductor device according to any one of Appendices 20 to 22, wherein
in the process of preparing the circuit pattern,
   the circuit pattern is provided on the upper surface of the insulating layer provided integrally with a cooler on one surface of the cooler.

### (Appendix 24)

The method of manufacturing a semiconductor device according to any one of Appendices 20 to 23, wherein
in the laser welding process,
   a laser irradiation time for simultaneously irradiating lasers of two or more wavelengths is provided.

### (Appendix 25)

A power conversion apparatus comprising:
a main conversion circuit that includes the semiconductor device according to any one of Appendices 1 to 19 and converts and outputs input power;
a drive circuit that outputs a drive signal for driving the semiconductor device to the semiconductor device; and
a control circuit that outputs a control signal for controlling the drive circuit to the drive circuit.

While the disclosure has been shown and described in detail, the foregoing description is in all aspects illustrative and not restrictive. It is therefore understood that numerous modifications and variations can be devised.

What is claimed is:

1. A semiconductor device comprising:
a circuit pattern provided on an upper surface of an insulating layer and electrically connected to a semiconductor element; and
a terminal including a bonding portion bonded to the circuit pattern and connectable to an external circuit,
wherein the bonding portion includes a region solid-phase bonded to the circuit pattern and a region laser-bonded thereto.

2. The semiconductor device according to claim 1, wherein the bonding portion includes an indentation formed on a surface of the bonding portion, which is a surface opposite to a back surface of the bonding portion bonded to the circuit pattern, in the region subjected to the solid-phase bonding.

3. The semiconductor device according to claim 1, wherein the bonding portion includes a melting mark formed on the surface of the bonding portion in the laser-bonded region.

4. The semiconductor device according to claim 3, wherein the indentation is formed around the melting mark on the surface of the bonding portion, and is not formed inside the melting mark on the surface of the bonding portion.

5. The semiconductor device according to claim 3, wherein the melting mark is formed from the surface of the bonding portion to a surface layer of the circuit pattern in a thickness direction of the bonding portion.

6. The semiconductor device according to claim 3, wherein the melting mark is formed in a line shape on the surface of the bonding portion.

7. The semiconductor device according to claim 3, wherein the melting mark is formed on an outer peripheral portion of the bonding portion.

8. The semiconductor device according to claim 3, wherein a thickness of the bonding portion in the melting mark is thinner than a thickness of the bonding portion around the melting mark.

9. The semiconductor device according to claim 1, further comprising at least one metal sheet provided between the back surface of the bonding portion and the circuit pattern,
wherein the terminal is bonded to the circuit pattern via the at least one metal sheet.

10. The semiconductor device according to claim 1, further comprising an insulating substrate including the insulating layer and the circuit pattern,
wherein the bonding portion of the terminal is arranged in parallel to the circuit pattern.

11. The semiconductor device according to claim 1, further comprising a cooler,
wherein the insulating layer is provided integrally with the cooler on one surface of the cooler, and
the bonding portion of the terminal is disposed parallel to the circuit pattern.

12. The semiconductor device according to claim 1, further comprising: an electrode having a plate shape and connectable to the external circuit,
wherein a bottom electrode of the semiconductor element is bonded to the circuit pattern, and
a top electrode of the semiconductor element is bonded to the electrode.

13. The semiconductor device according to claim 12, wherein
the electrode includes a through hole, and
the semiconductor element is bonded to the electrode via a bonding material filled in the through hole.

14. The semiconductor device according to claim 1, further comprising a heat dissipation plate having a plate shape or a block shape,
wherein a bottom electrode of the semiconductor element is bonded to the circuit pattern, and
a top electrode of the semiconductor element is bonded to the heat dissipation plate.

15. The semiconductor device according to claim 14, wherein
the heat dissipation plate includes a through hole, and
the semiconductor element is bonded to the heat dissipation plate via a bonding material filled in the through hole.

16. The semiconductor device according to claim 1, further comprising a heat dissipation layer provided on a lower surface of the insulating layer,
wherein a thickness of the circuit pattern is thicker than a thickness of the heat dissipation layer.

17. The semiconductor device according to claim 1, wherein the insulating layer is formed of any one of a ceramic material and a resin.

18. The semiconductor device according to claim 1, wherein the semiconductor element is an RC-IGBT.

19. The semiconductor device according to claim 1, wherein the semiconductor element is formed of a wide band gap semiconductor.

20. A method of manufacturing a semiconductor device, the method comprising:
a process of preparing a circuit pattern provided on an upper surface of an insulating layer and a terminal connectable to an external circuit; and
a process of bonding a bonding portion of the terminal to the circuit pattern,
wherein
the process of bonding the bonding portion of the terminal to the circuit pattern includes
a tacking process of solid-phase bonding the bonding portion of the terminal to the circuit pattern, and
a laser welding process of laser-bonding the bonding portion of the terminal to the circuit pattern after the tacking process.

21. The method of manufacturing a semiconductor device according to claim 20, wherein
the laser welding process includes:
irradiating a surface of the bonding portion opposite to a back surface of the bonding portion tacked to the circuit pattern by the solid-phase bonding with a laser to laser-bond the bonding portion to the circuit pattern.

22. The method of manufacturing a semiconductor device according to claim 20, wherein
the tacking process includes:
solid-phase bonding the bonding portion to the circuit pattern via at least one metal sheet provided between the back surface of the bonding portion and the circuit pattern.

23. The method of manufacturing a semiconductor device according to claim 20,
wherein
in the process of preparing the circuit pattern,
the circuit pattern is provided on the upper surface of the insulating layer provided integrally with a cooler on one surface of the cooler.

24. The method of manufacturing a semiconductor device according to claim 20, wherein
in the laser welding process,
a laser irradiation time for simultaneously irradiating lasers of two or more wavelengths is provided.

25. A power conversion apparatus comprising:
a main conversion circuit that includes the semiconductor device according to claim 1 and converts and outputs input power;
a drive circuit that outputs a drive signal for driving the semiconductor device to the semiconductor device; and
a control circuit that outputs a control signal for controlling the drive circuit to the drive circuit.
